(19) United States
(12) Patent Application Publication
(10) Pub. No.: US 2024/0333255 A1
(43) Pub. Date: Oct. 3, 2024

(54) RESONATOR ELEMENT AND RESONATOR DEVICE

(71) Applicant: SEIKO EPSON CORPORATION, Tokyo (JP)

(72) Inventors: Yusuke Yamamoto, Minowa-machi (JP); Keiichi Yamaguchi, Ina-shi (JP); Ryuta Nishizawa, Nagano-shi (JP)

(21) Appl. No.: 18/615,212

(22) Filed: Mar. 25, 2024

(30) Foreign Application Priority Data
Mar. 27, 2023 (JP) 2023-049537

(51) Int. Cl. H03H 9/17; H03H 9/19

(52) U.S. Cl. CPC H03H 9/178; H03H 9/19

(57) ABSTRACT

A resonator element includes a substrate including a thin-wall part and a thick-wall part, and an electrode part including an excitation electrode, a pad electrode, and an extraction electrode, wherein the electrode part includes a first electrode layer arranged in the pad electrode placement area and the first area on the substrate, a second electrode layer which is arranged in an area overlapping the first electrode layer on the first electrode layer, and which is larger in thickness than the first electrode layer, a third electrode layer which is arranged throughout an area overlapping the pad electrode placement area and the first area in a plan view on the second electrode layer, and an area overlapping the second area and the excitation electrode placement area in a plan view on the substrate, and which is smaller in thickness than the second electrode layer, and a fourth electrode layer which is arranged in an area overlapping the third electrode layer on the third electrode layer, and which is smaller in thickness than the second electrode layer.

The present application is based on, and claims priority from JP Application Serial Number 2023-049537, filed Mar. 27, 2023, the disclosure of which is hereby incorporated by reference herein in its entirety.

### BACKGROUND

### 1. Technical Field

The present disclosure relates to a resonator element and a resonator device.

### 2. Related Art

JP-A-2014-7693 (Document 1) discloses a piezoelectric resonator element having a so-called inverted mesa structure in which a recessed portion is formed in a part of a principal surface to achieve a higher frequency. This piezoelectric resonator element has a slit disposed between a thick-wall part for fixing the piezoelectric resonator element and a vibrating part in order to suppress the spread of stress caused by bonding/fixing. Further, the thickness of an extraction electrode is made thicker than the thickness of an excitation electrode in order to prevent an increase in sheet resistance in particular in the extraction electrode small in width for electrically coupling the excitation electrode and a pad electrode to each other due to a reduction in film thickness of an electrode for achieving the higher frequency.

However, in the piezoelectric resonator element in Document 1, a bonding member for mechanically and electrically coupling the piezoelectric resonator element to a package is bonded to a pad electrode. Therefore, when the thickness of the pad electrode is insufficient, there has been a problem that sufficient bonding strength between the piezoelectric resonator element and the bonding member cannot be obtained, and as a result, the mechanical coupling or the electrical coupling between the piezoelectric resonator element and the package becomes unstable.

### SUMMARY

A resonator a substrate element includes including a thin-wall part and a thick-wall part larger in thickness than the thin-wall part, and an electrode part including an excitation electrode arranged in an excitation electrode placement area of the thin-wall part, a pad electrode arranged in a pad electrode placement area of the thick-wall part, and an extraction electrode which is configured to couple the excitation electrode and the pad electrode to each other, and which is arranged in an extraction electrode placement area of the substrate, wherein the extraction electrode placement area includes a first area including a portion located in the thick-wall part, and a second area including a portion located in the thin-wall part, the electrode part includes a first electrode layer arranged in the pad electrode placement area and the first area on the substrate, a second electrode layer which is arranged in an area overlapping the pad electrode placement area and the first area in a plan view on the first electrode layer, and which is larger in thickness than the first electrode layer, a third electrode layer which is arranged throughout an area overlapping the pad electrode placement area and the first area in a plan view on the second electrode layer, and an area overlapping the second area and the excitation electrode placement area in a plan view on the substrate, and which is smaller in thickness than the second electrode layer, and a fourth electrode layer which is arranged throughout an area overlapping the pad electrode placement area, the extraction electrode placement area, and the excitation electrode placement area in a plan view on the third electrode layer, and which is smaller in thickness than the second electrode layer.

A resonator device includes the resonator element described above, and a package in which the resonator element is housed, and to which the resonator element is fixed via a bonding member.

### BRIEF DESCRIPTION OF THE DRAWINGS

FIG. 1 is a perspective view showing a configuration of a resonator element according to a first embodiment.

FIG. 2 is a diagram for explaining a relationship between an AT-cut crystal substrate and crystal axes of quartz crystal.

FIG. 3 is a plan view of the resonator element shown in FIG. 1.

FIG. 4 is a cross-sectional view along the line A1-A1 in FIG. 3.

FIG. 5 is a cross-sectional view along the line A2-A2 in FIG. 3.

FIG. 6 is a cross-sectional view along the line A3-A3 in FIG. 3.

FIG. 7 is a plan view showing a configuration of a resonator element according to a second embodiment.

FIG. 8 is a cross-sectional view along the line B1-B1 in FIG. 7.

FIG. 9 is a perspective view showing a configuration of a resonator element according to a third embodiment.

FIG. 10 is a cross-sectional view showing a configuration of a resonator device according to a fourth embodiment.

### DESCRIPTION OF EXEMPLARY EMBODIMENTS

### 1. First Embodiment

### 1.1. Resonator Element

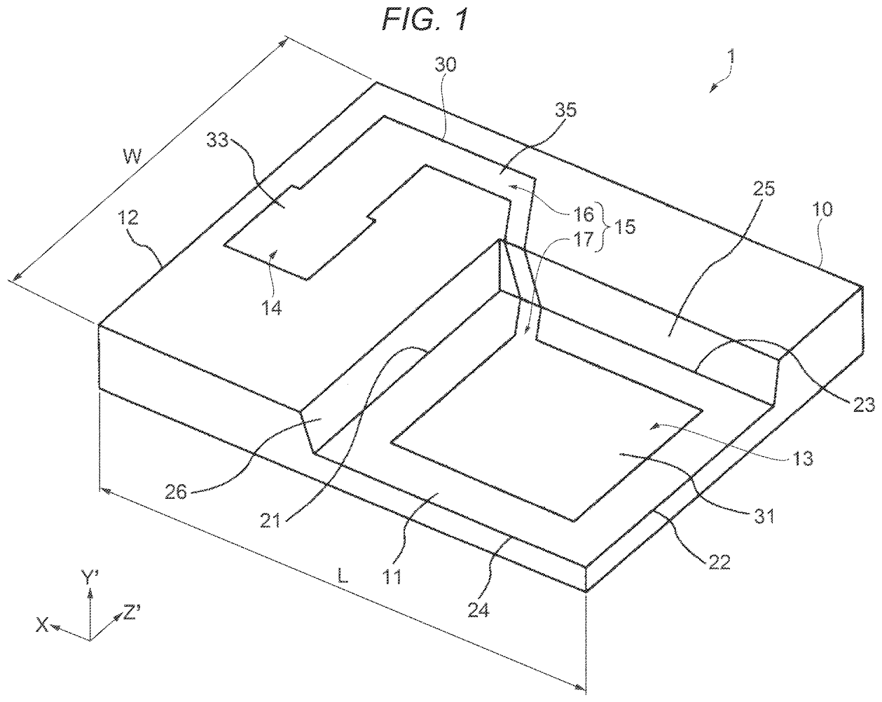

A resonator element 1 according to a first embodiment will be described with reference to FIG. 1 through FIG. 6.

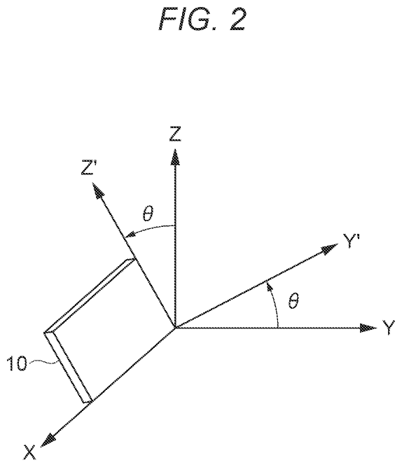

It should be noted that an X axis, a Y′ axis, and a Z′ axis are shown as three axes perpendicular to each other in the drawings hereinafter described except FIG. 2 for the sake of convenience of explanation. Further, a longitudinal direction of the resonator element 1 is referred to as an “X direction” as a direction along the X axis, a thickness direction of the resonator element 1 is referred to as a “Y′ direction” as a direction along the Y′ axis, and a direction perpendicular to the X axis and the Y′ axis is referred to as a “Z′ direction” as a direction along the Z′ axis. Further, an arrow side of each of the axes is also referred to as a “positive side,” and an opposite side to the arrow is also referred to as a “negative side.” Further, a positive side in the Y′ direction is also referred to as an “obverse side,” and a negative side in the Y′ direction is also referred to as a “reverse side.”

As shown in FIG. 1, the resonator element 1 according to the present embodiment has a substrate 10, and an electrode part 30 formed on the substrate 10.

The substrate 10 is a crystal substrate having a plate-like shape. Here, the quartz crystal as the material of the substrate 10 belongs to a trigonal system, and has crystal axes X, Y, and Z perpendicular to each other as shown in FIG. 2. The X axis, the Y axis, and the Z axis are called an electrical axis, a mechanical axis, and an optical axis, respectively. The substrate 10 in the present embodiment is a “rotated Y-cut crystal substrate” carved out along a plane obtained by rotating the X-Z plane around the X axis as much as a predetermined angle θ, and the substrate curved out along a plane obtained by the rotation as much as, for example, θ=35°15′ is referred to as an “AT-cut crystal substrate.” By using such a crystal substrate, the resonator element 1 having superior temperature characteristics is obtained.

It should be noted that the substrate 10 is not limited to the AT-cut crystal substrate providing the thickness-shear vibration can be excited, and for example, a BT-cut crystal substrate can also be used. Further, as the substrate 10, it is possible to use a variety of piezoelectric substrate made of, for example, lithium niobate or lithium tantalate besides the crystal substrate.

It should be noted that the Y axis and the Z axis rotated around the X axis in accordance with the angle θ are hereinafter referred to as the Y′ axis and the Z′ axis, respectively. In other words, the substrate 10 has a thickness in the Y′ direction, and has a spread in the X-Z′ plane direction.

The substrate 10 forms a longitudinal shape having a long side in the X direction, and a short side in the Z′ direction in a plan view. Further, the substrate 10 has a tip side at the −X direction side and a base end side at the +X direction side. Defining a maximum length in the X direction of the substrate 10 as L, and a maximum width in the Z′ direction thereof as W, a value L/W is not particularly limited, but is preferably set to, for example, about 1.1 through 1.4.

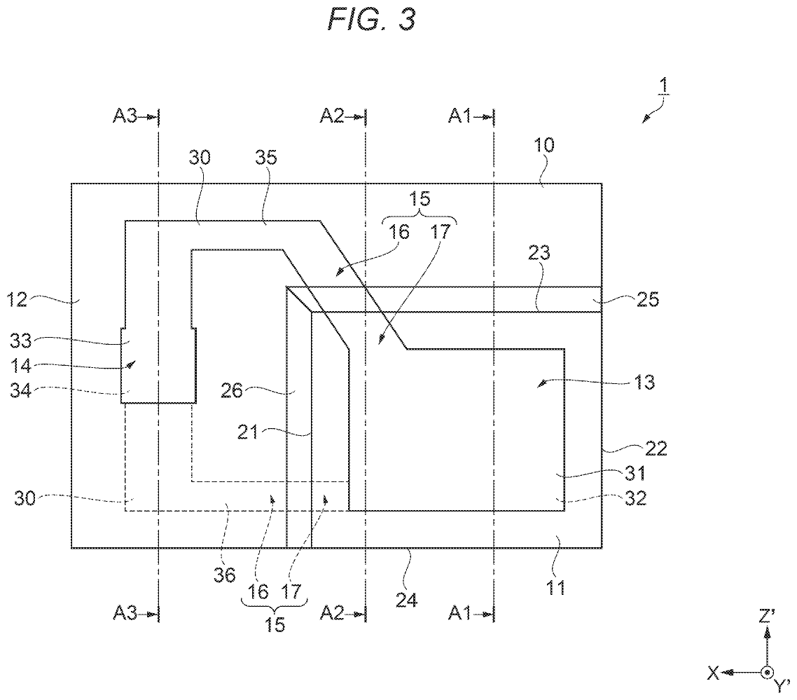

As shown in FIG. 1 and FIG. 3, the substrate 10 has a thin-wall part 11 in a vibrating region as a region where the vibration energy is confined, and a thick-wall part 12 which is integrated with the thin-wall part 11, and which is larger in thickness than the thin-wall part 11.

The thin-wall part 11 is displaced toward the negative side in the X direction and the negative side in the Z′ direction from the center of the substrate 10, and a part of an outer edge of the thin-wall part 11 is exposed from the thick-wall part 12. It is preferable that the area of the thin-wall part 11 is equal to or smaller than a half of the area of the substrate 10 in a plan view of the resonator element 1. Thus, it is possible to form the thick-wall part 12 higher in mechanical strength to be sufficiently large, and therefore, it is possible to sufficiently ensure the rigidity of the thin-wall part 11.

In the plan view of the resonator element 1, the thin-wall part 11 has a first outer edge 21 and a second outer edge 22 which are distant in the X direction as a vibration direction of the thickness-shear vibration from each other, and which extend in the Z′ direction, and a third outer edge 23 and a fourth outer edge 24 which are distant in the Z′ direction from each other, and which extend in the X direction. Out of the first outer edge 21 and the second outer edge 22, the first outer edge 21 is located at the positive side in the X direction, and the second outer edge 22 is located at the negative side in the X direction. Further, out of the third outer edge 23 and the fourth outer edge 24, the third outer edge 23 is located at the positive side in the Z′ direction, and the fourth outer edge 24 is located at the negative side in the Z′ direction. Further, the third outer edge 23 couples ends at the positive side in the Z′ direction of the first outer edge 21 and the second outer edge 22 to each other, and the fourth outer edge 24 couples ends at the negative side in the Z′ direction of the first outer edge 21 and the second outer edge 22 to each other.

Further, as shown in FIG. 1, an obverse surface as the principal surface at the positive side in the Y′ direction of the thick-wall part 12 is disposed so as to protrude toward the positive side in the Y′ direction from the obverse surface as the principal surface at the positive side in the Y′ direction of the thin-wall part 11. In contrast, a reverse surface as the principal surface at the negative side in the Y′ direction of the thick-wall part 12 is disposed on the same plane as the reverse surface as the principal surface at the negative side in the Y′ direction of the thin-wall part 11.

The thick-wall part 12 includes the thick-wall part 12 arranged along the first outer edge 21 and the thick-wall part 12 arranged along the third outer edge 23. Therefore, the thick-wall part 12 is provided with a structure of bending along the thin-wall part 11, and has a substantially L shape in the plan view. On the other hand, the thick-wall part 12 is not formed along the second outer edge 22 and the fourth outer edge 24 of the thin-wall part 11, and the second outer edge 22 and the fourth outer edge 24 are exposed from the thick-wall part 12. As described above, by partially disposing the thick-wall part 12 along the outer edges of the thin-wall part 11 to have the substantially L shape, and preventing the thick-wall part 12 from being disposed along the second outer edge 22 and the fourth outer edge 24, it is possible to reduce the mass at the tip side of the resonator element 1 while keeping the rigidity of the thin-wall part 11 of the resonator element 1. Further, it is possible to achieve a reduction in size of the resonator element 1.

The thick-wall part 12 is provided with a connection part 26 and a connection part 25 for connecting the thick-wall part 12 and the thin-wall part 11 to each other, wherein the connection part 26 is disposed continuously to the first outer edge 21, and has a tilted part gradually increasing in thickness toward the +X direction, and the connection part 25 is disposed continuously to the third outer edge 23, and has a tilted part gradually increasing in thickness toward the +Z′ direction. Further, the thick-wall part 12 at the connection part 26 side forms a mount part, and is fixed to a package or the like using an electrically-conductive adhesive or the like.

The electrode part 30 has a pair of excitation electrodes 31, 32, a pair of pad electrodes 33, 34, and a pair of extraction electrodes 35, 36.

The excitation electrodes 31, 32 are arranged in an excitation electrode placement area 13 of the thin-wall part 11. The excitation electrode 31 is formed on the obverse surface of the thin-wall part 11. In contrast, the excitation electrode 32 is arranged on the reverse surface of the thin-wall part 11 so as to be opposed to the excitation electrode 31. The excitation electrodes 31, 32 each have a substantially rectangular shape setting the longitudinal direction to the X direction, and the short-side direction to the Z′ direction.

The pad electrodes 33, 34 are arranged in a pad electrode placement area 14 of the thick-wall part 12. The pad electrode 33 is formed on the obverse surface of the thick-wall part 12 at the connection part 26 side. On the other hand, the pad electrode 34 is formed on the reverse surface of the thick-wall part 12 at the connection part 26 side so as to be opposed to the pad electrode 33.

The extraction electrodes 35, 36 are arranged in an extraction electrode placement area 15 of the substrate 10. It should be noted that the extraction electrode placement area 15 is constituted by a first area 16 including a portion located in the thick-wall part 12 including the connection parts 25, 26, and a second area 17 including a portion located in the thin-wall part 11. The extraction electrode 35 electrically couples the excitation electrode 31 and the pad electrode 33 to each other. On the other hand, the extraction electrode 36 electrically couples the excitation electrode 32 and the pad electrode 34 to each other. The extraction electrodes 35, 36 are disposed so as not to overlap each other via the substrate 10. Thus, it is possible to suppress the capacitance between the extraction electrodes 35, 36.

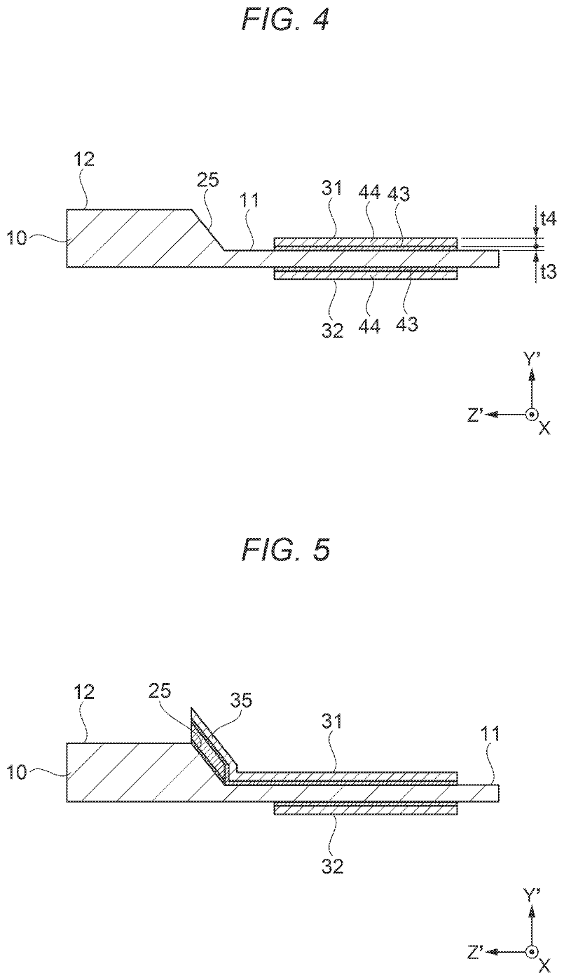

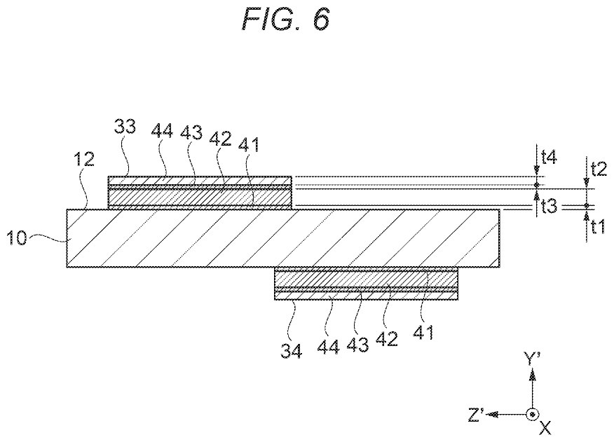

Further, as shown in FIG. 3, FIG. 4, FIG. 5, and FIG. 6, the electrode part 30 is constituted by the pad electrodes 33, 34, a part of the extraction electrode 35, and a part of the extraction electrode 36 each having metals of four layers, namely a first electrode layer 41, a second electrode layer 42, a third electrode layer 43, and a fourth electrode layer 44, stacked on one another, and a part of the extraction electrode 35, a part of the extraction electrode 36, and the excitation electrodes 31, 32 each having metals of two layers, namely the third electrode layer 43 and the fourth electrode layer 44, stacked on one another.

Specifically, the first electrode layer 41 is arranged in the pad electrode placement area 14 and the first area 16 on the substrate 10. The second electrode layer 42 is arranged in an area overlapping the pad electrode placement area 14 and the first area 16 in a plan view on the first electrode layer 41. It should be noted that the thickness t2 of the second electrode layer 42 is larger than the thickness t1 of the first electrode layer 41. Further, it is more preferable for the thickness t2 of the second electrode layer 42 to be three times or more of the thickness t4 of the fourth electrode layer 44 for controlling an increase in sheet resistance.

The third electrode layer 43 is arranged throughout an area overlapping the pad electrode placement area 14 and the first area 16 in a plan view on the second electrode layer 42, and an area overlapping the second area 17 and the excitation electrode placement area 13 in a plan view on the substrate 10. It should be noted that the thickness t3 of the third electrode layer 43 is smaller than the thickness t2 of the second electrode layer 42.

The fourth electrode layer 44 is arranged throughout an area overlapping the pad electrode placement area 14, the extraction electrode placement area 15, and the excitation electrode placement area 13 in a plan view on the third electrode layer 43. It should be noted that the thickness t4 of the fourth electrode layer 44 is smaller than the thickness t2 of the second electrode layer 42.

The constituent material of the electrode part 30 is gold (Au) in the second electrode layer 42 and the fourth electrode layer 44, and is at least one of nickel (Ni), chromium (Cr), and chromium nitride (CrN) in the first electrode layer 41 and the third electrode layer 43.

As described hereinabove, in the resonator element 1 according to the present embodiment, the pad electrodes 33, 34 and the extraction electrode 35, 36 having a four-layered structure are disposed in the thick-wall part 12 including the connection parts 25, 26 of the substrate 10, and the excitation electrodes 31, 32 and the extraction electrodes 35, 36 having a double-layered structure are disposed in the thin-wall part 11. Therefore, it is possible to set the thickness of the excitation electrodes 31, 32 to a thickness with which unwanted spurious is difficult to occur, and to set the thickness of the extraction electrodes 35, 36 to a thickness with which the sheet resistance is difficult to increase, and to set the thickness of the pad electrodes 33, 34 to a thickness with which sufficient bonding strength can be obtained. Therefore, it is possible to obtain the resonator element 1 which is excellent in vibration characteristics, and is excellent in mechanical reliability or electrical reliability.

### 1.2. Method of Manufacturing Resonator Element

Then, a method of manufacturing the resonator element 1 will be described.

The method of manufacturing the resonator element. 1 includes a thin-wall part formation step of reducing the wall thickness of a part of the substrate 10, a first electrode part formation step of forming an electrode on the substrate 10, and a second electrode part formation step of forming an electrode on the first electrode part and the thin-wall part.

### 1.2.1. Thin-Wall Part Formation Step

An etching protective film made of gold (Au) or the like is formed on both surfaces of the substrate 10 using a deposition apparatus such as a sputtering apparatus. Then, a protective film mask for forming a recessed part is formed on the obverse surface of the substrate 10 using a photolithography technology or an etching technology.

Then, wet etching is performed on the substrate 10 via the protective film mask using an etching liquid such as a compound liquid of hydrofluoric acid and ammonium fluoride to provide the thin-wall part 11 to the substrate 10.

### 1.2.2. First Electrode Part Formation Step

The first electrode layer 41 made of chromium (Cr) or the like and the second electrode layer 42 made of gold (Au) or the like are formed in a stacked manner on the both sides of the substrate 10 provided with the thin-wall part 11 using the deposition apparatus such as a sputtering apparatus. Subsequently, the pad electrodes 33, 34 and the extraction electrodes 35, 36 are formed in the pad electrode placement area 14 and the first area 16 of the extraction electrode placement area 15 on the substrate 10 using the photolithography technology and the etching technology.

### 1.2.3. Second Electrode Part Formation Step

The third electrode layer 43 made of chromium (Cr) or the like and the fourth electrode layer 44 made of gold (Au) or the like are formed in a stacked manner on the both sides of the substrate 10 provided with the pad electrodes 33, 34 and the extraction electrodes 35, 36 in the pad electrode placement area 14 and the first area 16 of the extraction electrode placement area 15 using the deposition apparatus such as a sputtering apparatus. Subsequently, the pad electrodes 33, 34, the extraction electrodes 35, 36, and the excitation electrodes 31, 32 are formed in the area overlapping the pad electrode placement area 14 and the first area 16 of the extraction electrode placement area 15 on the second electrode layer 42, and the second area 17 of the extraction electrode placement area 15 and the excitation electrode placement area 13 on the substrate 10 using the photolithography technology and the etching technology.

Due to the manufacturing method described hereinabove, it is possible to manufacture the resonator element 1 in which the pad electrodes 33, 34 and the extraction electrode 35, 36 having the four-layered structure are disposed in the thick-wall part 12 including the connection parts 25, 26 of the substrate 10, and the excitation electrodes 31, 32 and the extraction electrodes 35, 36 having the double-layered structure are disposed in the thin-wall part 11. Therefore, it is possible to set the thickness of the excitation electrodes 31, 32 to a thickness with which unwanted spurious is difficult to occur, and to set the thickness of the extraction electrodes 35, 36 to a thickness with which the sheet resistance is difficult to increase, and to set the thickness of the pad electrodes 33, 34 to a thickness with which sufficient bonding strength can be obtained. Therefore, it is possible to obtain the resonator element 1 which is excellent in vibration characteristics, and is excellent in mechanical reliability or electrical reliability.

### 2. Second Embodiment

### 2.1. Resonator Element

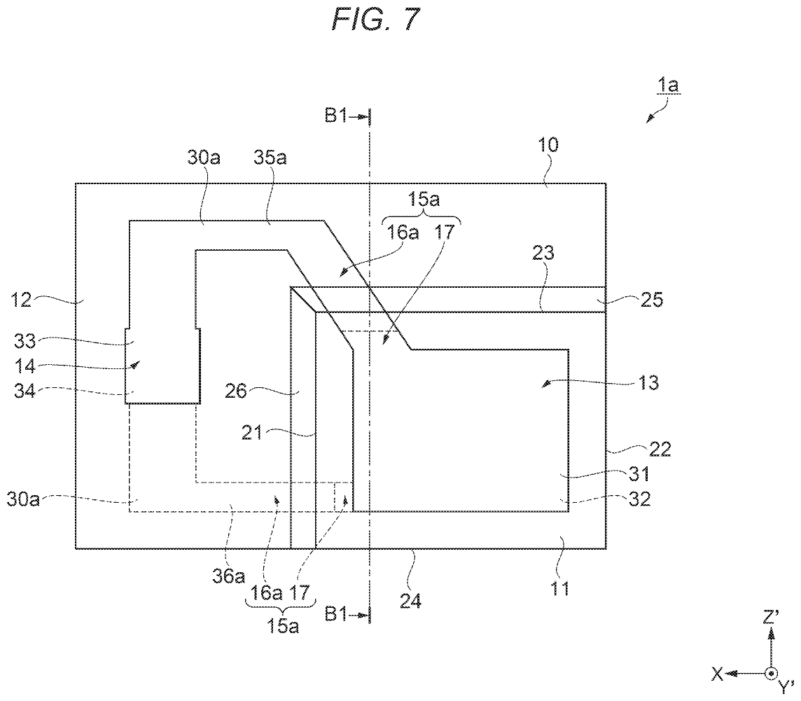

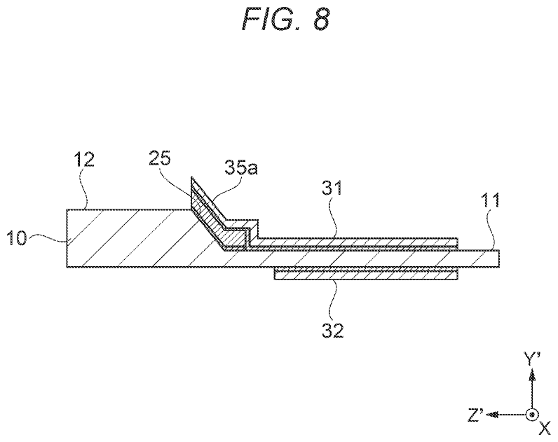

Then, a resonator element 1a according to a second embodiment will be described with reference to FIG. 7 and FIG. 8.

The resonator element 1a according to the present embodiment is substantially the same as the resonator element 1 according to the first embodiment except the point that a placement position configuration of an electrode part 30a is different from that of the resonator element 1 according to the first embodiment. It should be noted that there is presented the description with a focus on the differences from the first embodiment described above, and regarding substantially the same matters, the same reference symbols are provided, and the explanation thereof will be omitted.

As shown in FIG. 7, the resonator element 1a has the substrate 10, and the electrode part 30a formed on the substrate 10.

The electrode part 30a of the resonator element 1a is constituted by the pad electrodes 33, 34 having the four-layered structure, extraction electrodes 35a, 36a having the double-layered structure, and the excitation electrodes 31, 32 having the double-layered structure. A first area 16a of an extraction electrode placement area 15a where the extraction electrodes 35a, 36a having the four-layered structure are formed includes a portion located in the thin-wall part 11. In other words, as shown in FIG. 8, the extraction electrode 35a having the four-layered structure is provided to the thick-wall part 12 including the connection part 25 and a part of the thin-wall part 11.

By adopting such a configuration in the resonator element 1a, it is possible to shorten the extraction electrodes 35a, 36a having the double-layered structure, and thus, it is possible to further suppress the increase in sheet resistance. Therefore, it is possible to obtain the resonator element 1a which is excellent in bonding strength, and which is low in CI value.

### 3. Third Embodiment

### 3.1. Resonator Element

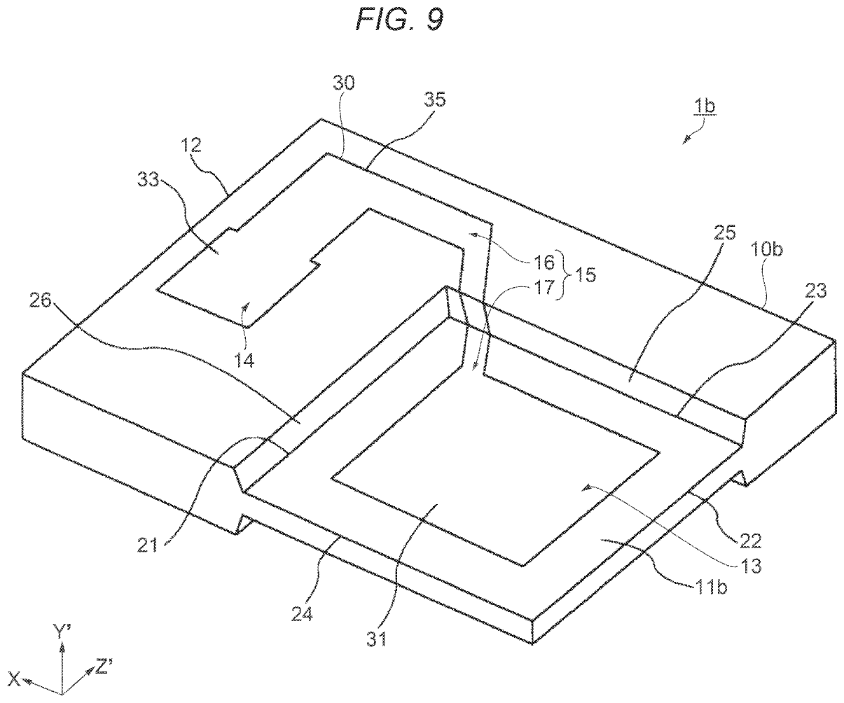

Then, a resonator element 1b according to a third embodiment will be described with reference to FIG. 9.

The resonator element 1b according to the present embodiment is substantially the same as the resonator element 1 according to the first embodiment except the point that a shape of a substrate 10b is different from that of the resonator element 1 according to the first embodiment. It should be noted that there is presented the description with a focus on the differences from the first embodiment described above, and regarding substantially the same matters, the same reference symbols are provided, and the explanation thereof will be omitted.

As shown in FIG. 9, the resonator element 1b has a substrate 10b, and the electrode part 30 formed on the substrate 10b.

In the substrate 10b of the resonator element 1b, the obverse surface as the principal surface at the positive side in the Y′ direction of the thick-wall part 12 is disposed so as to protrude toward the positive side in the Y′ direction from the obverse surface as the principal surface at the positive side in the Y′ direction of a thin-wall part 11b. Meanwhile, a reverse surface as the principal surface at the negative side in the Y′ direction of the thick-wall part 12 is disposed so as to protrude toward the negative side in the Y′ direction from the reverse surface as the principal surface at the negative side in the Y′ direction of the thin-wall part 11b. In other words, the thin-wall part 11b is formed by forming recessed portions on the both surfaces of the substrate 10b. Therefore, in the manufacturing method, it is possible to make the etching depth of the recessed portions shallower to achieve a reduction in cost compared to the first embodiment described above.

By adopting such a configuration to the resonator element 1b, it is possible to obtain the resonator element 1b which is excellent in bonding strength, and which is low in cost.

### 4. Fourth Embodiment

### 4.1. Resonator Device

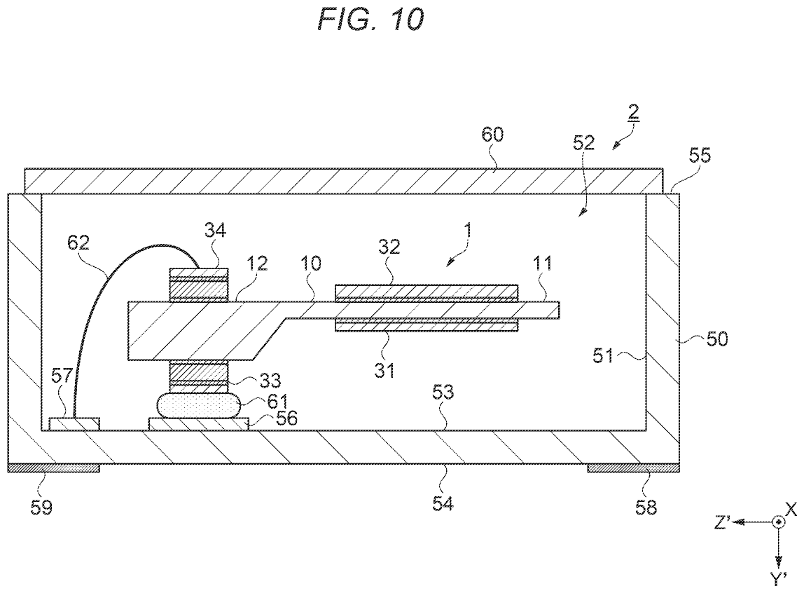

Then, a resonator device 2 according to a fourth embodiment will be described with reference to FIG. 10. It should be noted that in the present description, the explanation is presented citing the resonator device 2 equipped with the resonator element 1 described above as an example.

As shown in FIG. 10, the resonator device 2 has the resonator element 1, a package 50 for housing the resonator element 1, and a lid 60 for forming a housing space 52 with the package 50.

The package 50 has a recess 51 opening on a first surface 55, and the lid 60 for covering the opening of the recess 51 is bonded to the first surface 55. By covering the recess 51 of the package 50 with the lid 60, the housing space 52 for housing the resonator element 1 is formed. The housing space 52 can be kept in a reduced-pressure state or a vacuum state, or can be filled with an inert gas such as nitrogen (N), helium (He), or argon (Ar).

The constituent material of the package 50 is not particularly limited, and a variety of types of ceramics such as aluminum oxide can be used as the constituent material. Further, the constituent material of the lid 60 is not particularly limited, and a member with a linear expansion coefficient similar to that of the constituent material of the package 50 is preferable. It should be noted that bonding between the package 50 and the lid 60 is not particularly limited, and it is possible to bond the package 50 and the lid 60 with, for example, an adhesive or seam welding.

On an inner bottom surface 53 of the package 50, there are formed connection electrodes 56, 57. Further, on a second surface 54 of the package 50, there are formed external mounting terminals 58, 59. The connection electrode 56 is electrically coupled to the external mounting terminal 58 via a through electrode not shown provided to the package 50, and the connection electrode 57 is electrically coupled to the external mounting terminal 59 via a through electrode not shown provided to the package 50.

The resonator element 1 housed in the housing space 52 is fixed to the package 50 with a bonding member 61 as an electrically-conductive adhesive in a mount part of the thick-wall part 12 so that a surface as the principal surface at the positive side in the Y′ direction of the thick-wall part 12 faces to the package 50. The bonding member 61 is disposed so as to have contact with the connection electrode 56 and the pad electrode 33. Thus, the connection electrode 56 and the pad electrode 33 are electrically coupled to each other via the bonding member 61. By supporting the resonator element 1 at one place or a single point using the bonding member 61, it is possible to suppress, for example, the stress caused in the resonator element 1 by a difference in thermal expansion coefficient between the package 50 and the substrate 10.

The pad electrode 34 of the resonator element 1 is electrically coupled to the connection electrode 57 via a bonding wire 62. As described above, the pad electrode 34 is arranged so as to be opposed to the pad electrode 33, and is therefore located immediately above the bonding member 61 in the state in which the resonator element 1 is fixed to the package 50. Therefore, it is possible to suppress the leakage of the ultrasonic vibration provided to the pad electrode 34 when performing the wire bonding, and thus, it is possible to more reliably achieve the connection of the bonding wire 62 to the pad electrode 34.

Further, the pad electrodes 33, 34 have the four-layered structure, and therefore have a sufficient thickness. Therefore, it is possible to sufficiently ensure the bonding strength with the bonding member 61 and the bonding strength with the bonding wire 62. Therefore, the resonator device 2 in which the resonator element 1 provided with the pad electrodes 33, 34 having the sufficient bonding strength is fixed in the package 50 is excellent in mechanical reliability or electrical reliability.

By adopting such a configuration, since the resonator device 2 is provided with the resonator element 1 in which the thickness of the excitation electrodes 31, 32 is set to the thickness with which the unwanted spurious is difficult to occur, the thickness of the extraction electrodes 35, 36 is set to the thickness with which the sheet resistance is difficult to increase, and the thickness of the pad electrodes 33, 34 is set to the thickness with which the sufficient bonding strength can be obtained, it is possible to obtain the resonator device 2 which has good vibration characteristics, and which is excellent in mechanical reliability or electrical reliability.

What is claimed is:

1. A resonator element comprising:
a substrate including a thin-wall part and a thick-wall part larger in thickness than the thin-wall part; and
an electrode part including an excitation electrode arranged in an excitation electrode placement area of the thin-wall part, a pad electrode arranged in a pad electrode placement area of the thick-wall part, and an extraction electrode which is configured to couple the excitation electrode and the pad electrode to each other, and which is arranged in an extraction electrode placement area of the substrate, wherein
the extraction electrode placement area includes a first area including a portion located in the thick-wall part, and a second area including a portion located in the thin-wall part,
the electrode part includes
a first electrode layer arranged in the pad electrode placement area and the first area on the substrate,
a second electrode layer which is arranged in an area overlapping the pad electrode placement area and the first area in a plan view on the first electrode layer, and which is larger in thickness than the first electrode layer,
a third electrode layer which is arranged throughout an area overlapping the pad electrode placement area and the first area in a plan view on the second electrode layer, and an area overlapping the second area and the excitation electrode placement area in a plan view on the substrate, and which is smaller in thickness than the second electrode layer, and
a fourth electrode layer which is arranged throughout an area overlapping the pad electrode placement area, the extraction electrode placement area, and the excitation electrode placement area in a plan view on the third electrode layer, and which is smaller in thickness than the second electrode layer.

2. The resonator element according to claim 1, wherein
the thickness of the second electrode layer is three times or more of the thickness of the fourth electrode layer.

3. The resonator element according to claim 1, wherein
the first area includes a portion located in the thin-wall part.

4. The resonator element according to claim 2, wherein
the first area includes a portion located in the thin-wall part.

5. The resonator element according to claim 1, wherein
the substrate includes a connection part which is configured to connect the thick-wall part and the thin-wall part to each other, and which has a tilted part, and
the first area includes a portion located in the thin-wall part and the connection part in a plan view.

6. The resonator element according to claim 1, wherein
the second electrode layer and the fourth electrode layer are made of gold, and
the first electrode layer and the third electrode layer include at least one of nickel, chromium, and chromium nitride.

7. The resonator element according to claim 5, wherein
the second electrode layer and the fourth electrode layer are made of gold, and
the first electrode layer and the third electrode layer include at least one of nickel, chromium, and chromium nitride.

8. A resonator device comprising:
the resonator element according to claim 1; and
a package in which the resonator element is housed, and to which the resonator element is fixed via a bonding member.
